(19) United States
(12) Patent Application Publication
(10) Pub. No.: US 2018/0309084 A1
(43) Pub. Date: Oct. 25, 2018

(54) DISPLAY DEVICE

(71) Applicant: Innolux Corporation, Miao-Li County (TW)

(72) Inventors: Shu-Ci JHOU, Miao-Li County (TW); Chi-Che TSAI, Miao-Li County (TW); Po-Ching LIN, Miao-Li County (TW)

(21) Appl. No.: 15/953,579

(22) Filed: Apr. 16, 2018

(30) Foreign Application Priority Data
Apr. 25, 2017 (CN) 201710274825.6

(51) Int. Cl. H01L 51/52; H01L 51/56; H01L 51/00

(52) U.S. Cl. CPC H01L 51/525; H01L 51/5246; H01L 51/56; H01L 27/3244; H01L 2251/558; H01L 2251/301; H01L 51/5243; H01L 51/0094

(57) ABSTRACT

A display device includes a first substrate, a second substrate disposed opposite to the first substrate, a display unit disposed between the first substrate and the second substrate, a spacing body disposed between the first substrate and the second substrate and surrounding the display unit, and an adhesive member including silane compound, a first portion of the adhesive member disposed between the spacing body and the first substrate.

This application claims the benefit of People's Republic of China application Serial No. 201710274825.6, filed Apr. 25, 2017, the subject matters of which are incorporated herein by references.

### BACKGROUND

### Technical Field

The disclosure relates in general to a display device, and more particularly to an encapsulation of a display device.

### Description of the Related Art

Electronic products with display panel, such as smart phones, tablets, notebooks, monitors, and TVs, have become indispensable necessities to modern people no matter in their work, study or entertainment. With a flourishing development of the portable electronic products, the consumers not only pursue better electronic characteristics such as higher display quality, higher speed of response, longer life span and higher reliability, but also have higher expects on the functions of the products to be more diversified. Moreover, it is an important matter to the consumers whether the electronic products are light-weight and easy to carry.

With the more humanized and more diversified developments of the electronic products, the product design becomes more precise, and the requirement of the resistance to the water vapor and oxygen is relatively increased. If the amount of the water vapor and/or oxygen penetrated into the electronic device exceeds an acceptable amount of the applied device, it causes the oxidation and degradation in the elements of the device, thereby affecting the display quality and shortening the operation lifetime of the electronic device. General indicators for judging the capability of a water vapor and/or oxygen barrier layer include the water vapor transmission rate (WVTR, g/m²/day), and the oxygen transmission rate (OTR, cm³/m²/day). Various displays have their acceptable moisture penetrating amounts. For example, OTR and WVTR required for the barrier layer on the substrate of the liquid crystal display (LCD) must be no more than about 0.1 cm³/m²/day and about 0.1 g/m²/day, respectively. The organic light emitting diode display (OLED) has the most severe requirement on the water vapor and/or oxygen blocking rate, wherein the required WVTR and OTR are typically not over 1×10⁻⁶ g/m²/day, and 10⁻⁵ to 10⁻³ cm³/m²/day, respectively.

### SUMMARY

The disclosure is directed to a display device, comprising an encapsulation structure formed by a spacing body and an adhesive member having silane compound for achieving assembly and encapsulation of the upper and lower substrates.

According to one embodiment of the present disclosure, a display device is provided, comprising a first substrate; a second substrate disposed oppositely to the first substrate; a display unit, disposed between the first substrate and the second substrate; a spacing body, disposed between the first substrate and the second substrate and surrounding the display unit; an adhesive member, comprising silane compound, a first portion of the adhesive member disposed between the spacing body and the first substrate.

The disclosure will become apparent from the following detailed description of the preferred but non-limiting embodiments. The following description is made with reference to the accompanying drawings.

### BRIEF DESCRIPTION OF THE DRAWINGS

FIG. 1 is a cross-sectional view of a display device according to the first embodiment of the disclosure.

FIG. 2 is a cross-sectional view of a display device according to the second embodiment of the disclosure.

FIG. 3 illustrates an adhesive force between the silane compound of the adhesive member and the spacing body according to one embodiment of the disclosure.

FIG. 4 is an enlarging view of the spacing body and the silane compound of FIG. 2.

### DETAILED DESCRIPTION

In the embodiments of the present disclosure, a display device comprising an encapsulation structure formed by a spacing body and a silane compound is provided, for lowering the probability of the penetration of water vapor and/or oxygen into the display device, thereby prolonging the operation lifetime of the display device. Also, the embodiments of the disclosure can be applied to various types of the display devices, especially suitable for being applied to the display device having substrates required to be assembled at a low temperature (ex: the plastic substrates). Deformation of plastic substrates at a high temperature may not be a concern during the implementation of the embodiment. Accordingly, a high manufacturing yield of a display device can be achieved by applying the encapsulation structure as provided by the embodiment, and the display device applied by the embodiment has stable and high display quality.

The embodiments of the disclosure can be applied to a display device having flexible substrates, but the disclosure is not limited thereto. The embodiments of the disclosure can also be applied to a display device having rigid substrates, or a display device having at least one flexible substrate. Also, the embodiments of the disclosure can be applied to an encapsulation of substrate peripheries for a display device having active-matrix organic light-emitting diodes (AMOLEDs) or passive-matrix organic light-emitting diodes (PMOLEDs). The display devices with other displaying types can be applied by the embodiments. Additionally, the types of the switching units on the substrate of the display device are not particularly limited. The switching units on the substrate of the display device can be (but not limited to) back-channel-etch (BCE) type thin film transistors (TFTs), etch-stop layer type TFTs, top-gate type TFTs and bottom-gate type TFTs. Also, materials of the semiconductor layer of TFTs are not limited; for example, amorphous silicon, polysilicon and metal oxides are all applicable. The embodiments are described in details with reference to the accompanying drawings. It is noted that the details of the structures and procedures of the embodiments are provided for exemplification, and the described details of the embodiments are not intended to limit the present disclosure. It is noted that not all embodiments of the disclosure are shown. Modifications and variations can be made without departing from the spirit of the disclosure to meet the requirements of the practical applications. Thus, there may be other embodiments of the present disclosure which are not specifically illustrated. Further, the accompany drawings are simplified for clear illustrations of the embodiment; sizes and proportions in the drawings are not directly proportional to actual products, and shall not be construed as limitations to the present disclosure. Thus, the specification and the drawings are to be regard as an illustrative sense rather than a restrictive sense. Also, the identical and/or similar elements of the embodiments are designated with the same and/or similar reference numerals.

Moreover, use of ordinal terms such as “first”, “second”, “third”, etc., in the specification and claims to modify an element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements. Also, when a first material layer being formed at, on or above a second material layer have been described in the embodiments, it includes the condition of the first material layer contacting the second material layer. It also includes conditions of one or more material layers disposed between the first material layer and the second material layer, wherein the first material layer would be not directly contact the second material layer. Additionally, the terms for describing join and connection, such as “connect”, “join to each other”, etc., can be referred to two structures in direct contact or in non-direct contact (i.e. other structure disposed therebetween), unless specially defined. Also, the terms for describing join and connection can be referred to two moveable structures or two fastened structures.

### First Embodiment

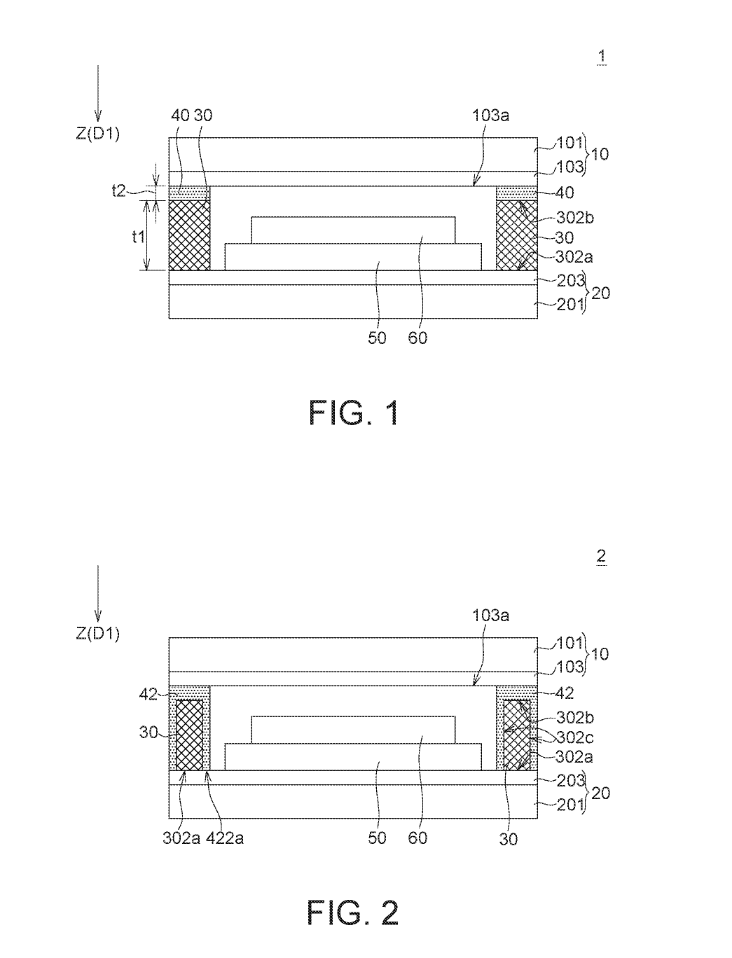

FIG. 1 is a cross-sectional view of a display device according to the first embodiment of the disclosure. The display device 1 of the first embodiment includes a first substrate 10, a second substrate 20 disposed opposite to the first substrate 10, a display unit 60 disposed between the two substrates, a spacing body 30 disposed between the first substrate 10 and the second substrate 20 and disposed correspondingly to the peripheries of the two substrates, an adhesive member 40 at least disposed between the spacing body 30 and the first substrate 10, wherein the adhesive member 40 is in contact with a lower surface 103a of the first substrate 10. In some examples, the adhesive member 40 comprises silane compound. In the embodiment, the first substrate 10 is disposed opposite to the second substrate 20. The spacing body 30 has a first thickness t1 along a first direction D1 perpendicular to the first substrate 10 (such as Z-direction), the adhesive member 40 between the spacing body 30 and the first substrate 10 has a second thickness t2 along the first direction D1, wherein the first thickness t1 is greater than the second thickness t2, as shown in FIG. 1. In some examples, the first direction D1 is perpendicular to the lower surface 103a of the first substrate 10. In other examples, FIG. 1 may only illustrate the display area of the display device 1, and the first substrate 10 and the second substrate 20 of the display device 1 may further extend and have electrical components (such as IC chips) on the outside of the spacing body 30.

In one embodiment, the display unit 60 is disposed above the second substrate 20, wherein the spacing body 30 surrounds the display unit 60. In one embodiment, the spacing body 30 surrounding the display unit 60 means that the spacing body 30 at least surrounds the display area of the display unit 60. However, the disclosure is not limited thereto. In other embodiment, the spacing body 30 may surround the periphery area of the display device 1. In one embodiment, the adhesive member 40 is at least formed at the upper surface 302b of the spacing body 30. The person of ordinary skill in the art should understand that although FIG. 1 only illustrates one display unit 60, the display device 1 may include a plurality of display units 60 depending on the needs. The spacing body 30 and the adhesive member 40 may surround each of the display units 60 or surround at least a portion of the display units 60. In one embodiment, the spacing body 30 may surround the display area of the substrate including a plurality of display units 60.

In one embodiment, the display device 1 further comprises a thin film transistor (TFT) array 50 disposed on the second substrate 20, and a display unit 60 disposed on the TFT array 50. Thus, the spacing body 30 and the adhesive member 40 are disposed around the display area of the substrate, wherein the spacing body 30 and the adhesive member 40 at least formed at the upper surface 302b of the spacing body 30 surround the display unit 60. The first substrate 10 and the second substrate 20 are assembled to each other by curing (e.g., rapid low-temperature laser curing the adhesive member 40, thereby generating a closed space to lower the probability of penetration of water vapor and/or oxygen into the device. In other words, the first substrate 10 and the second substrate 20 are encapsulated by the spacing body 30 and the adhesive member 40. Also, the display unit 60 may include liquid crystal (LC), organic light-emitting diodes (OLEDs), quantum dots (QDs), fluorescence molecules, phosphor molecules, light-emitting diodes (LEDs), mini light-emitting diodes (mini LEDs), micro light-emitting diodes (micro LEDs) or other display mediums. The disclosure has no particular limitation thereto. In some examples, the chip size of the light-emitting diodes may be in a range between 300 μm and 10 mm. The chip size of the mini light-emitting diodes may be in a range between 100 μm and 300 μm. The chip size of the micro light-emitting diodes may be in a range between 1 μm and 100 μm. The disclosure has no particular limitation thereto. In one embodiment, the display unit 60 includes the organic light-emitting diodes (OLEDs), and the spacing body 30 and the adhesive member 40 can be formed as an encapsulation structure of the organic light-emitting diodes to lower the probability of the penetration of water vapor and/or oxygen into the device, so that the organic light-emitting diodes would not be deteriorated and the operation lifetime of the display device can be prolonged.

In the embodiment, the TFT array 50 disposed above the second substrate 20 may comprise plural thin film transistors, plural scan lines, plural data lines, plural electrodes, plural passive components (such as capacitors and resistors), alignment films and/or driving circuits; however, the disclosure is not limited thereto. According to the embodiment, the TFT array 50 can be the thin film transistors in the display area, or can be the components of the circuit design in the peripheral area. Also, the first substrate 10 of the display device can be a color filter substrate having plural color filters, electrodes, black matrix, alignment films, spacers, protective films or other components; the disclosure is not limited thereto. It is noted that the components not related to the spacing body 30 and the adhesive member 40 of the embodiment are omitted from the first substrate 10 and the second substrate 20 in the drawings, for clearly illustrating the embodiment.

As shown in FIG. 1, the first substrate 10 may comprise a first base layer 101 and a first buffer layer 103, wherein the adhesive member 40 contacts and adheres to the first buffer layer 103. The second substrate 20 may comprise a second base layer 201 and a second buffer layer 203, wherein a lower surface 302a of the spacing body 30 is disposed on the second buffer layer 203. In one embodiment, the adhesive member 40 can be adhered to the spacing body 30 by covalent bonding, or hydrogen bonds occur between the silane compound 40 and the first buffer layer 103. However, the disclosure is not limited thereto. In other embodiment, the adhesive member 40 can be adhered to the spacing body 30 or the first buffer layer 103 by other adhesive forces. Additionally, a single inorganic layer is depicted in the drawings for illustrating the first buffer layer 103 and the second buffer layer 203, but the disclosure is not limited thereto. The first buffer layer 103 or the second buffer layer 203 can be a single-layered structure (such as a single inorganic layer), a multi-layered structure (such as several inorganic layers or a multi-inorganic layered structure) or other single-layered or multi-layered structure formed from the materials resistant to water vapor and/or oxygen penetration. In one embodiment, at least one of the first buffer layer 103 and the second buffer layer 203 is a laminated structure of multi-layers including oxides, nitrides, or a combination thereof.

In one embodiment, the spacing body 30 can be formed during manufacturing the TFT array 50. For example, the spacing body 30 can be fabricated by using the first metal layer, the second metal layer, or the insulating layer of the thin film transistors. Therefore, the spacing body 30 and the metal layer (such as the first metal layer or the second metal layer) of the TFT array 50 or the insulating layer of the TFT array 50 may comprise the same material. In other words, the material of the spacing body 30 is the same as the material of parts of the components of the TFT array 50. In other embodiment, the spacing body 30 and the TFT array 50 can be fabricated separately by choosing other applicable materials. The disclosure has no particular limitation thereto. In one embodiment, material examples of the spacing body 30 include (but not limited to) metals, metal oxides, metal nitrides, non-metallic oxides and non-metallic nitrides. According to one embodiment, the material of the spacing body 30 has an extremely low water vapor transmission rate (WVTR), such as less than 1×10⁻⁶ g/m²/day.

Also, in one embodiment, The adhesive member 40 includes the silane compound, and the silane compound comprises one or more silane coupling agents, wherein the silane coupling agents comprise organic functional groups, such as (but not limited to) a vinyl group, an epoxy group, a styryl group, a methacryloxy group, an acryloxy group, or an amino group. Examples of the silane coupling agents include (but are not limited to vinyltrichlorosilane, vinyltrimethoxysilane, vinyltriethoxysilane, 2-(3,4 epoxycyclohexyl)-ethyltrimethoxysilane, 3-glycidoxypropyl trimethoxysilane, 3-glycidoxypropyl methyldiethoxysilane, 3-glycidoxypropyl triethoxysilane, p-Styryltrimethoxysilane, 3-methacryloxypropyl methyldimethoxysilane, 3-methacryloxypropyl trimethoxysilane, 3-methacryloxypropyl methyldiethoxysilane, 3-methacryloxypropyl triethoxysilane, 3-acryloxypropyl trimethoxysilane, N-2(aminoethyl) 3-amino propylmethyldimethoxysilane, N-2(aminoethyl) 3-amino propyltrimethoxysilane, N-2(aminoethyl) 3-amino propyltriethoxysilane, 3-aminopropyl trimethoxysilane, 3-aminopropyl triethoxysilane, 3-triethoxysilyl-N-(1,3 dimethyl-butyliden) propylamine, and/or N-phenyl-3-aminopropyl trimethoxysilane. According to one embodiment, the material(s) of the adhesive member 40 has an extremely low water vapor transmission rate (WVTR), such as less than 1×10⁻⁶ g/m²/day.

Moreover, the disclosure can be applied to the flexible-type display devices or non-flexible-type display devices. The disclosure has no particular limitation thereto. For example, the first substrate 10 and the second substrate 20 of the embodiment in the application can be flexible substrates, non-flexible substrates, or a combination thereof. The first base layer 101 and the second base layer 201 can be independently selected from the flexible plate or rigid plate; for example, both of the base layers are flexible plates, or rigid plates, or one is a flexible plate and the other is a rigid plate.

Additionally, the materials of the first base layer 101 and the second base layer 201 of the embodiment are not limited particularly. Metals, plastics, resins, glass fibers, carbon fibers, or other polymeric materials are applicable. In one embodiment, material examples of a plastic base layer include polyethylene naphthalate (PEN), polyethyleneterephthalate (PET), polycarbonate (PC), polyimide (PI), and/or cycloolefin polymer (COP). For the plastic (or polymer) base layers, when a glass frit sealing for encapsulation (e.g., frit melting and curing by a laser beam need to operate at a temperature of 400° C.-600° C.) is conducted, the plastic (or polymer) base layers would be deformed at a high temperature process. However, when the embodiment is applied to an application for substrate assembly, a laser beam can rapidly scan over the silane compound 40 by a localized manner, wherein the curing and adhesion for substrate assembly can be implemented at a lower heating temperature (e.g., about 100° C.) for a shortened heating time (e.g., in a range from a few seconds to 20 seconds). Therefore, there is no limitation for the applicable materials of the base layer of the substrate. The high-temperature-resistant materials (such as glass) and the non-high-temperature-resistant materials (such as plastics) are all applicable for forming the base layers of the disclosure.

Practically, the materials of the layers of the substrate, such as the materials of the first base layer 101 or the second base layer 201, can be selected according to the requirements of the practical application, such as the flexibility, toughness and stiffness required by a display device of the application. The features of the disclosure can be applied to different types of the applications, such as the applications having non-flexible base layers (ex: thick glass) or flexible base layers (e.g., plastics, thin glass or ultra-thin glass), by adequate modification and changes. The first base layer 101 and the second base layer 201 can be made of the same material or different materials. The thickness t_{S1} of the first base layer 101 and the thickness t_{S2} of the second base layer 201 can be the same or different. The disclosure has no particular limitation thereto. In one embodiment, the first base layer 101 and the second base layer 201 are glass plates or plastic plates. Alternatively, the first base layer 101 and the second base layer 201 are a plastic plate and a glass plate, respectively. The glass plates mentioned herein can be non-flexible thick glass plates or flexible thin or ultra-thin glass plates.

In one embodiment, each of the first base layer 101 and the second base layer 201 is an ultra-thin glass plate, wherein the thickness of the ultra-thin glass plate can be in a range of larger than or equal to 0.001 mm to less than or equal to 0.2 mm. For example, the thickness of the ultra-thin glass plate can be 0.15 mm, 0.1 mm, 0.05 mm, 0.01 mm or other numerical values. The ultra-thin glass plate has characteristics of the excellent flexibility and the relatively light-weight, which can be provided as the base layer for the substrate of a thin-type display device and a flexible-type display device. In other embodiment, each of the first base layer 101 and the second base layer 201 can be a thin glass plate, wherein the thickness of the thin glass plate can be in a range of larger than 0.2 mm to less than or equal to 0.3 mm. For example, the thickness of the thin glass plate can be 0.3 mm, 0.25 mm or other numerical values. The thin glass plate has characteristics of the general flexibility and the general light-weight feature, which can be provided as the base layer for the substrate of a thin-type display device and a flexible-type display device. In another embodiment, each of the first base layer 101 and the second base layer 201 can be a thick glass; for example, the thickness of the thick glass plate can be in a range of larger than 0.3 mm to less than 1 mm. For example, the thickness of the thick glass plate can be 0.5 mm, 0.7 mm or other numerical values. The thick glass plate has better toughness and higher stiffness, which can meet the requirements of the processes performed by the general processing machines. In one embodiment, the first base layer 101 and the second base layer 201 may be one of the ultra-thin glass plate, the thin glass plate, the thick glass plate, and other material plates, respectively. The first base layer 101 and the second base layer 201 may comprise different materials. The first base layer 101 or the second base layer 201 can be flexible base layer or non-flexible base layer; the selection of the materials of the base layers depends on the actual needs of the practical application.

According to the aforementioned descriptions, since the silane compound 40 provides adhesive force for assembling the upper and lower substrates, it is no need to form a thick silane compound. Moreover, the capability of the water vapor and/or oxygen resistance of the silane compound 40 is not as great as that of the spacing body 30. Therefore, the thickness of the adhesive member 40 of the embodiment can be reduced (such as less than 1 μm and greater than 0 μm), so that assembly of the upper and lower substrates can be achieved without sacrificing the capability of the water vapor and/or oxygen resistance. As shown in FIG. 1, the thickness (e.g., the second thickness t2) of the adhesive member 40 of the embodiment is less than the thickness (e.g., the first thickness t1) of the spacing body 30, thereby significantly decreasing the cross-sectional area of the path through which the water vapor and/or oxygen penetrates into the display device. Accordingly, the display device of the embodiment with an extremely low water vapor transmission rate (WVTR), such as less than 1×10⁻⁶ g/m²/day, can be achieved. Also, the disclosure is suitable for being applied to the display device having different types of the substrates, such as the glass substrates assembled at a high temperature or, in particular, the plastic substrates assembled at a low temperature. Deformation of plastic substrates at a high temperature would not be a concern during the implementation of the embodiment.

### Second Embodiment

FIG. 2 is a cross-sectional view of a display device according to the second embodiment of the disclosure. The display device 1 of the first embodiment and the display device 2 of the second embodiment have an identical structure, except that the adhesive member 42 of the display device 2 of the second embodiment is further disposed at the sidewalls 302c of the spacing body 30 and contacts the second buffer layer 203. Also, the identical elements of the display devices in the first and second embodiments are designated with the same reference numerals. Thus, please refer to the related descriptions in the first embodiment above for the structure details and spatial arrangements of the layers/components of the substrates in the second embodiment, and the contents will not be redundantly repeated.

As shown in FIG. 2, the display device 2 of the second embodiment also includes a first substrate 10, a second substrate 20 disposed opposite to the first substrate 10, a display unit 60 disposed between the two substrates, a spacing body 30 disposed between the first substrate 10 and the second substrate 20 and disposed correspondingly to the peripheries of the two substrates, an adhesive member 42 at least disposed between the spacing body 30 and the first substrate 10, wherein the adhesive member 42 is in contact with the lower surface 103a of the first substrate 10. In examples, the adhesive member 42 may cover all of the sidewalls of the spacing body 40. In some examples, the adhesive member 42 may cover a portion of the sidewalls of the spacing body 40, and the adhesive member 42 may not reach the surface of the second buffer layer 203. The adhesive member 42 may include silane compound. The display unit 60 is disposed above the second substrate 20, wherein the adhesive member 42 surrounds the display unit 60. Also, the lower surface 302a of the spacing body 30 is disposed on the second buffer layer 203 of the second substrate 20, and the adhesive member 42 is disposed on the upper surface 302b and at least a portion of the sidewalls 302c of the spacing body 30, wherein the adhesive member 42 contacts the second buffer layer 203. In this embodiment, the adhesive member 42 substantially covers the upper surface 302b and all of the sidewalls 302c of the spacing body 30. Besides adhering to the first buffer layer 103 of the first substrate 10, the adhesive member 42 as enclosing the spacing body 30 also adheres to the second buffer layer 203 of the second substrate 20 to accomplish tight connection and encapsulation. Two substrates are assembled by curing the adhesive member 42 (e.g. low-temperature fast curing by laser beam), thereby generating a closed or encapsulated space to lower the probability of the penetration of water vapor and/or oxygen into the display unit 60. As shown in FIG. 2, the lower surface 422a of the adhesive member 42 and the lower surface 302a of the spacing body 30 contact and/or adhere to the second buffer layer 203. The upper surface 302b of the spacing body 30 does not contact the first buffer layer 103. The upper surface 302b of the spacing body 30 and the first buffer layer 103 are separated by the adhesive member 42. In some examples, the material of the spacing body 30 comprises a silicon nitride (SiNx).

In the embodiment, the first buffer layer 103 and the second buffer layer 203 can be a single-layered structure (such as a single inorganic layer), a multi-layered structure (such as several inorganic layers or a multi-inorganic layered structure) or other single-layered or multi-layered structure formed from the materials resistant to water vapor and/or oxygen penetration. In one embodiment, at least one of the first buffer layer 103 and the second buffer layer 203 is a laminated structure of multi-layers including oxides and/or nitrides. Also, please refer to the first embodiment for the applicable materials of the base layers, the spacing body 30 and the adhesive member 42, and the details are not redundantly repeated.

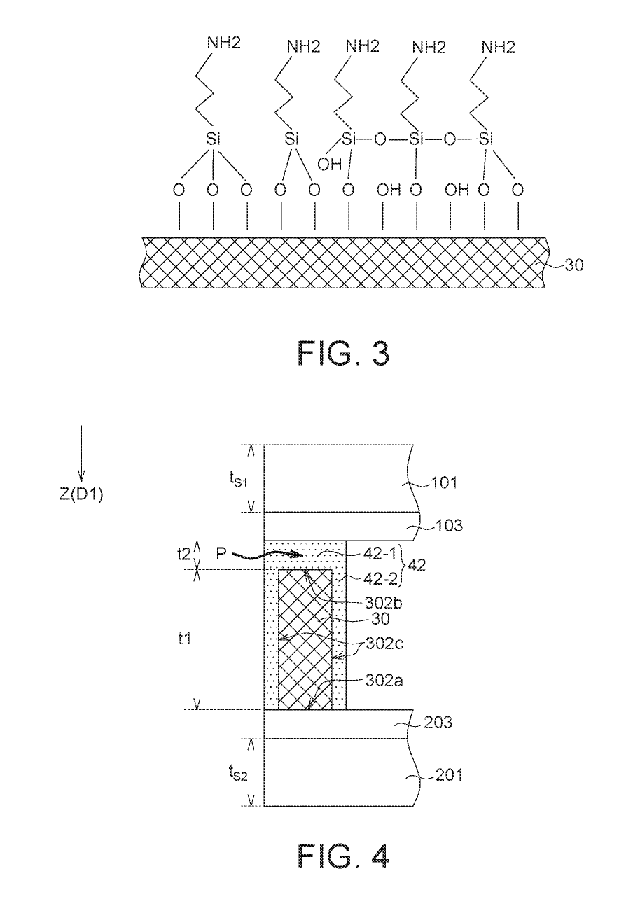

In one embodiment, the adhesive member 42 (including silane compound as described above) can be adhered to the first buffer layer 103 and the second buffer layer 203 by hydrogen bonds. The adhesive member 42 can also be adhered to the first buffer layer 103 and the second buffer layer 203 by other adhesive forces. The disclosure has no particular limitation thereto. FIG. 3 illustrates an adhesive force between the silane compound of the adhesive member 42 and the spacing body (or the first buffer layer 103/the second buffering layer 203) according to one embodiment of the disclosure. In one embodiment, the functional groups (such as amino groups) of the adhesive member 42 (contacting the first buffer layer 103) adhere to the first buffer layer 103 and/or the second buffering layer 203 by hydrogen bonds. In some examples, at least one of the first buffer layer 103 and/or the second buffering layer 203 comprises silicon nitride (SiNx). The material itself of the adhesive member 42 or the OH groups after hydrolysis of the adhesive member 42 can be adhered to the spacing body 30 by forming covalent bonds, as shown in FIG. 3.

FIG. 4 is an enlarging view of the spacing body and the silane compound of FIG. 2. According to the embodiment, the thickness (e.g., the second thickness t2) of the adhesive member 42 of the embodiment is less than the thickness (ex: the first thickness t1) of the spacing body 30, as shown in FIG. 4. Therefore, the cross-sectional area of the path through which the water vapor and/or oxygen penetrates into the display device can be significantly decreased, and the display device of the embodiment with an extremely low water vapor transmission rate (WVTR) can be achieved. The arrow in FIG. 4 denotes a water vapor and/or oxygen penetration path P, and a cross-sectional area of the silane compound 42 above the spacing body 30 is small (e.g., less than the distance between the first substrate 10 and the second substrate 20) according to the design of the embodiment, thereby lowering the probability of the penetration of the water vapor and/or oxygen into the display device.

Additionally, a single inorganic layer is depicted in the drawings for illustrating each of the buffer layers, but the disclosure is not limited thereto. The first buffer layer 103 or the second buffer layer 203 can be a single-layered structure (such as a single inorganic layer), a multi-layered structure (such as several inorganic layers or a multi-inorganic layered structure) or other single-layered or multi-layered structure formed from the materials resistant to water vapor and/or oxygen penetration. Also, the embodiment illustrates a first portion 42-1 (e.g. the portion having the first thickness t1) of the adhesive member 42 disposed on the upper surface 302b of the spacing body 30, or illustrates the first portion 42-1 of the adhesive member 42 disposed on the upper surface 302b and a second portion 42-2 (e.g. the portion having the second thickness t2) of the adhesive member 42 covering all of the sidewalls 302c of the spacing body 30, the disclosure, however, is not limited thereto. In other embodiment, the adhesive member 42 may be disposed on the lower surface 302a or part of the sidewalls 302c of the spacing body 30. Thus, the adhesive member 42 of the embodiment can be formed on at least parts of the upper surface 302b of the spacing body 30, at least parts of the sidewalls 302c of the spacing body 30, at least parts of the lower surface 302a of the spacing body 30, or at the positions from any combination thereof.

According to the aforementioned descriptions, the display device of the embodiment comprises an encapsulation structure formed by the spacing body 30 and the adhesive member 40/42. When the embodiment is applied for encapsulating a display unit of a display device, it may lower the probability of the penetration of water vapor and/or oxygen into the display device. Accordingly, the encapsulation structure of the embodiment can be applied to a display device using organic light-emitting diode (OLED) technology which is sensitive to the amounts of water vapor and/or oxygen, thereby lower the probability of the penetration of water vapor and/or oxygen from penetrating into the display device and deteriorating the OLEDs. Accordingly, the display device of the embodiment with an extremely low water vapor transmission rate (WVTR), such as less than 1×10⁻⁶ g/m²/day, can be achieved, and the operation lifetime of the display device can be prolonged. Also, the embodiments of the disclosure can be applied to a flexible type or non-flexible type display device and/or substrates and/or base layers; the disclosure has no particular limitation thereto. Additionally, the materials of the base layers (e.g., the first base layer 103 and the second base layer 203) of the substrate of the embodiment are not limited particularly. The high-temperature-resistant materials such as glass, or the non-high-temperature-resistant materials such as plastics or other materials are all applicable for forming the base layers of the disclosure. Thus, the disclosure can be applied to various types of the display devices, especially suitable for being applied to the display device having substrates required to be assembled at a low temperature (e.g., the plastic substrates). Deformation of plastic substrates at a high temperature would not be a concern during the implementation of the embodiment. Accordingly, a high manufacturing yield of a display device can be achieved by applying the encapsulation structure as provided by the embodiment, and the display device applied by the embodiment has stable and high display quality.

In the aforementioned embodiments, the technique features described in one embodiment are not limited to the application of that embodiment. Structural details of the aforementioned embodiments are provided for exemplification only, not for limitation. It is, of course, noted that the features of different embodiments can be combined and rearranged without departing from the spirit and scope of the present disclosure. Other embodiments with different configurations, such as change on components of the related layers and the displaying elements to meet practical requirements can be applicable. It is known by people skilled in the art that the configurations and the procedure details of the related components/layers could be adjusted according to the requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A display device, comprising:
a first substrate;
a second substrate, disposed opposite to the first substrate;
a display unit, disposed between the first substrate and the second substrate;
a spacing body, disposed between the first substrate and the second substrate and surrounding the display unit; and
an adhesive member, comprising silane compound, a first portion of the adhesive member disposed between the spacing body and the first substrate.

2. The display device according to claim 1, wherein the spacing body has a first thickness along a first direction perpendicular to the first substrate, the first portion of the adhesive member has a second thickness along the first direction, and the second thickness is less than the first thickness.

3. The display device according to claim 2, wherein the second thickness is less than 1 μm and greater than 0 μm.

4. The display device according to claim 1, wherein the first substrate comprises a first buffer layer, and the adhesive member is in contact with the first buffer layer.

5. The display device according to claim 4, wherein the first buffer layer comprises silicon nitride.

6. The display device according to claim 4, wherein the first buffer layer is a multi-layered structure.

7. The display device according to claim 1, wherein the adhesive member further comprises a second portion disposed on a sidewall of the spacing body.

8. The display device according to claim 7, wherein the second substrate comprises a second buffer layer, and the second portion is in contact with the second buffer layer.

9. The display device according to claim 8, wherein the second buffer layer comprises silicon nitride.

10. The display device according to claim 1, wherein the silane compound comprises a vinyl group, an epoxy group, a styryl group, a methacryloxy group, an acryloxy group, or an amino group.

11. The display device according to claim 10, wherein the silane compound comprising the vinyl group comprises vinyltrichlorosilane, vinyltrimethoxysilane, and vinyltriethoxysilane.

12. The display device according to claim 10, wherein the silane compound comprising the epoxy group comprises 2-(3, 4 epoxycyclohexyl)-ethyltrimethoxysilane, 3-glycidoxypropyl trimethoxysilane, 3-glycidoxypropyl methyldiethoxysilane, and 3-glycidoxypropyl triethoxysilane.

13. The display device according to claim 10, wherein the silane compound comprising the styryl group comprises p-styryltrimethoxysilane.

14. The display device according to claim 10, wherein the silane compound comprising the methacryloxy group comprises 3-methacryloxypropyl methyldimethoxysilane, 3-methacryloxypropyl trimethoxysilane, 3-methacryloxypropyl methyldiethoxysilane, and 3-methacryloxypropyl triethoxysilane.

15. The display device according to claim 10, wherein the silane compound comprising the acryloxy group comprises 3-acryloxypropyl trimethoxysilane.

16. The display device according to claim 10, wherein the silane compound comprising the amino group comprises N-2(aminoethyl) 3-amino propylmethyldimethoxysilane, N-2(aminoethyl) 3-amino propyltrimethoxysilane, N-2(aminoethyl) 3-amino propyltriethoxysilane, 3-aminopropyl trimethoxysilane, 3-aminopropyl triethoxysilane, 3-triethoxysilyl-N-(1,3 dimethyl-butyliden) propylamine, and N-phenyl-3-aminopropyl trimethoxysilane.

17. The display device according to claim 1, further comprising a thin film transistor (TFT) array disposed on the second substrate, and the display unit disposed on the TFT array.

18. The display device according to claim 1, wherein the display unit comprises an organic light-emitting diode.

19. The display device according to claim 1, wherein the spacing body comprises a metal, an oxide, or a nitride.
